(19) United States
(12) Patent Application Publication
(10) Pub. No.: US 2024/0213287 A1
(43) Pub. Date: Jun. 27, 2024

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventor: HIROSHI HORIKOSHI, KANAGAWA (JP)

(21) Appl. No.: 18/557,062

(22) PCT Filed: Jan. 12, 2022
(86) PCT No.: PCT/JP2022/000801

§ 371 Date: Oct. 25, 2023

(30) Foreign Application Priority Data
May 17, 2021 (JP) 2021-083485

(51) Int. Cl. H01L 27/146

(52) U.S. Cl. CPC H01L 27/14636; H01L 27/14645

(57) ABSTRACT

A solid-state imaging device and an electronic apparatus include: a first pixel provided on a side of a first surface serving as a side from which light enters of a first base, and a second pixel that is disposed in a first direction on the first surface to be adjacent to the first pixel; a first signal terminal that is provided in a region corresponding to a center portion of the first pixel on a side of a second surface of the first base and is coupled to the first pixel; a second signal terminal that is provided in a region corresponding to a center portion of the second pixel and is coupled to the second pixel; a first shield terminal that is provided in a region corresponding to a side of the second pixel of a peripheral portion of the first pixel on the side of the second surface; and a second shield terminal that is provided in a region corresponding to a side of the first pixel of a peripheral portion of the second pixel on the side of the second surface and is provided in a region displaced in a second direction with respect to the first shield terminal.

### TECHNICAL FIELD

The present disclosure relates to a solid-state imaging device and an electronic apparatus.

### BACKGROUND ART

For example, PTL 1 discloses an imaging device in which three substrates including a first substrate, a second substrate, and a third substrate are stacked and are electrically coupled to each other with a through wiring line. In the imaging device, a periphery of one through wiring line (for example, a first through wiring line) is shielded by another through wiring line (for example, a third through wiring line) coupled to a reference potential. It is thus possible to prevent noise generated in one pixel signal from being transferred to another pixel signal between adjacent sensor pixels, and this makes it possible to improve noise resistance performance of the imaging device.

### CITATION LIST

### Patent Literature

PTL 1: Japanese Unexamined Patent Application Publication No. 2020-88380

### SUMMARY OF THE INVENTION

By the way, regarding an imaging device, electric reliability is desired, for example, for bonding between a through wiring line of a first substrate and a through wiring line of a second substrate. Accordingly, in order to improve the electric reliability of the imaging device by suppressing or preventing noise generated between adjacent pixels and reliably bonding the through wiring lines between the stacked substrates, there is still room for improvement.

It is therefore desirable to provide a solid-state imaging device and an electronic apparatus that makes it possible to improve the electric reliability.

A first solid-state imaging device according to an embodiment of the present disclosure includes: a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel; a first signal terminal that is provided in a region corresponding to a center portion of the first pixel, on a side of a second surface opposite to the side of the first surface of the first base, and is coupled to the first pixel; a second signal terminal that is provided in a region corresponding to a center portion of the second pixel, on the side of the second surface of the first base, and is coupled to the second pixel; a first shield terminal that is provided in a region corresponding to a side of the second pixel of a peripheral portion of the first pixel, on the side of the second surface of the first base, and is supplied with a fixed potential; and a second shield terminal that is provided in a region corresponding to a side of the first pixel of a peripheral portion of the second pixel, on the side of the second surface of the first base, is provided in a region displaced in a second direction on the second surface intersecting the first direction with respect to the first shield terminal, and is supplied with a fixed potential.

An electronic apparatus according to an embodiment of the present disclosure includes the first solid-state imaging device according to the embodiment of the present disclosure.

A second solid-state imaging device according to an embodiment of the present disclosure includes: a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel; a first signal terminal that is provided in a region corresponding to a center portion of the first pixel, on a side of a second surface opposite to the side of the first surface of the first base, and is coupled to the first pixel; a second signal terminal that is provided in a region corresponding to a center portion of the second pixel, on the side of the second surface of the first base, and is coupled to the second pixel; and a first shield terminal that is provided in a region corresponding to a side of the second pixel of a peripheral portion of the first pixel, on the side of the second surface of the first base, is formed to be entirely overlapped with the second signal terminal in a second direction on the second surface intersecting the first direction, as viewing the second signal terminal from the first signal terminal in the first direction, and is supplied with a fixed potential.

An electronic apparatus according to an embodiment of the present disclosure includes the second solid-state imaging device according to the embodiment of the present disclosure.

In the first solid-state imaging device and the electronic apparatus according to the embodiment of the present disclosure, the second shield terminal provided in the region corresponding to a side of the first pixel of the peripheral portion of the second pixel is provided in a region displaced in the second direction with respect to the first shielded terminal provided in the region corresponding to the side of the second pixel of the peripheral portion of the first pixel. As a result, the first shield terminal and the second shield terminal serve as a shield region and effectively suppress or prevent noise between the first pixel and the second pixel adjacent to each other.

In addition, the second shield terminal is provided to be displaced with respect to the first shield terminal, the shield region is enlarged, and this makes it possible to reduce plane areas of the first shield terminal and the second shield terminal. As a result, a difference between the plane areas of the first signal terminal, the second signal terminal, the first shield terminal, and the second shield terminal is reduced, and occurrence of a recess in a terminal bonding surface caused by pattern dependency is effectively suppressed or prevented.

In the second solid-state imaging device and the electronic apparatus according to the embodiment of the present disclosure, the first shield terminal is provided in the region corresponding to the side of the second pixel of the peripheral portion of the first pixel. The first shield terminal is formed to be entirely overlapped with the second signal terminal in the second direction, as viewing the second signal terminal from the first signal terminal in the first direction. As a result, the first shield terminal is formed as the shield region and effectively suppresses or prevents the noise between the first pixel and the second pixel adjacent to each other.

In addition, the first shield terminal forms the shield region in a shape entirely overlapped with the second signal terminal in the second direction, as viewing the second signal terminal from the first signal terminal in the first direction. Therefore, it is possible to reduce the plane area of the first shield terminal. As a result, it is possible to reduce a difference between the plane areas of the first signal terminal, the second signal terminal, and the first shield terminal, and it is possible to effectively suppress or prevent the occurrence of the recess in the terminal bonding surface caused by the pattern dependency.

### BRIEF DESCRIPTION OF DRAWING

FIG. 1 is a main part cross-sectional diagram illustrating pixels and a pixel circuit of a solid-state imaging device according to a first embodiment of the present disclosure.

FIG. 2 is a main part plan view for explaining an arrangement layout of terminals on a pixel side illustrated in FIG. 1.

FIG. 3 is a circuit diagram of the pixels and the pixel circuit illustrated in FIG. 1.

FIG. 4 is a main part plan view corresponding to FIG. 2, for describing the arrangement layout of the terminals on the pixel side and an arrangement layout of terminals on a pixel circuit side illustrated in FIG. 1.

FIG. 5 is a main part cross-sectional diagram of the terminals on the pixel side and the terminals on the pixel circuit side illustrated in FIG. 4.

FIG. 6 is a main part cross-sectional diagram of terminals on a pixel side and terminals on a pixel circuit side according to a comparative example, corresponding to FIG. 5.

FIG. 7 is a main part plan view corresponding to FIG. 2, for describing an arrangement layout of terminals on a pixel side of a solid-state imaging device according to a second embodiment of the present disclosure.

FIG. 8 is a main part plan view corresponding to FIG. 2, for describing an arrangement layout of terminals on a pixel side of a solid-state imaging device according to a third embodiment of the present disclosure.

FIG. 9 is a main part plan view corresponding to FIG. 2, for describing an arrangement layout of terminals on a pixel side of a solid-state imaging device according to a fourth embodiment of the present disclosure.

FIG. 10 is a main part cross-sectional diagram corresponding to FIG. 1, illustrating pixels and a pixel circuit of a solid-state imaging device according to a fifth embodiment of the present disclosure.

FIG. 11 is a main part plan view corresponding to FIG. 2, for describing an arrangement layout of terminals on a side of the pixel illustrated in FIG. 10.

FIG. 12 is a block diagram depicting an example of schematic configuration of a vehicle control system.

FIG. 13 is a diagram of assistance in explaining an example of installation positions of an outside-vehicle information detecting section and an imaging section.

FIG. 14 is a diagram illustrating a second application example according to an embodiment of the present disclosure, and is a view depicting an example of a schematic configuration of an endoscopic surgery system.

FIG. 15 is a block diagram depicting an example of a functional configuration of a camera head and a camera control unit (CCU).

FIG. 16 is a block diagram illustrating a configuration example of an electronic apparatus to which the present technology is applied.

### MODES FOR CARRYING OUT THE INVENTION

The following describes embodiments of the present disclosure in detail with reference to the accompanying drawings. It should be noted that the description is given in the following order.

### 1. First Embodiment

In the first embodiment, an example in which the present technology is applied to a solid-state imaging device is described.

### 2. Second Embodiment

In the second embodiment, a first example in which an arrangement layout of terminals in the solid-state imaging device according to the first embodiment is changed is described.

### 3. Third Embodiment

In the third embodiment, a second example in which the arrangement layout of the terminals in the solid-state imaging device according to the first embodiment is changed is described.

### 4. Fourth Embodiment

In the fourth embodiment, a third example in which an arrangement layout of terminals in a solid-state imaging device according to the third embodiment is changed is described.

### 5. Fifth Embodiment

In the fifth embodiment, an example is described in which the present technology is applied to a solid-state imaging device that adopts a SPAD structure.

### 6. Example of Application to Mobile Body

An example is described in which the present technology is applied to a vehicle control system that is an example of a mobile body control system.

### 7. Example of Application to Endoscopic Surgery System

An example is described in which the present technology is applied to an endoscopic surgery system.

### 8. Example of Application to Electronic Apparatus

An example is described in which the present technology is applied to an electronic apparatus.

### 9. Other Embodiments

### 1. First Embodiment

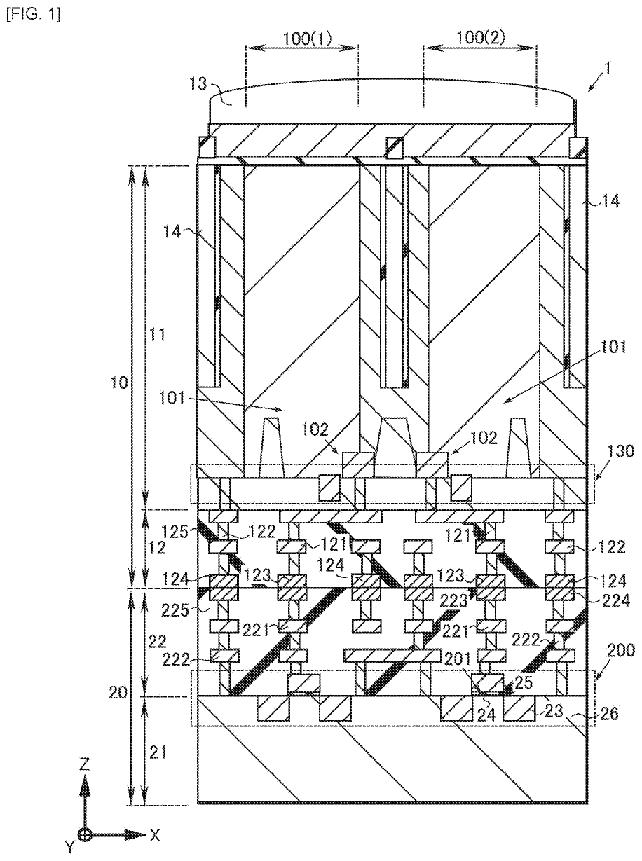

A solid-state imaging device 1 according to a first embodiment of the present disclosure is described with reference to FIGS. 1 to 6.

Here, in the drawings, an arrow X direction indicated as needed indicates one planar direction of the solid-state imaging device 1 placed on a plane, for convenience. An arrow Y direction indicates another planar direction perpendicular to the arrow X direction. Furthermore, an arrow Z direction indicates an upward direction perpendicular to the arrow X direction and the arrow Y direction. That is, the arrow X direction, the arrow Y direction, and the arrow Z direction respectively and exactly match an X-axis direction, a Y-axis direction, and a Z-axis direction of the three-dimensional coordinate system.

Note that each of these directions is indicated for easy understanding of description and does not limit directions of the present technology.

### [Configuration of Solid-State Imaging Device 1]

### (1) Circuit Configuration of Pixels 100, Pixel Circuit 130, and Image Processing Circuit 200 of Solid-State Imaging Device 1

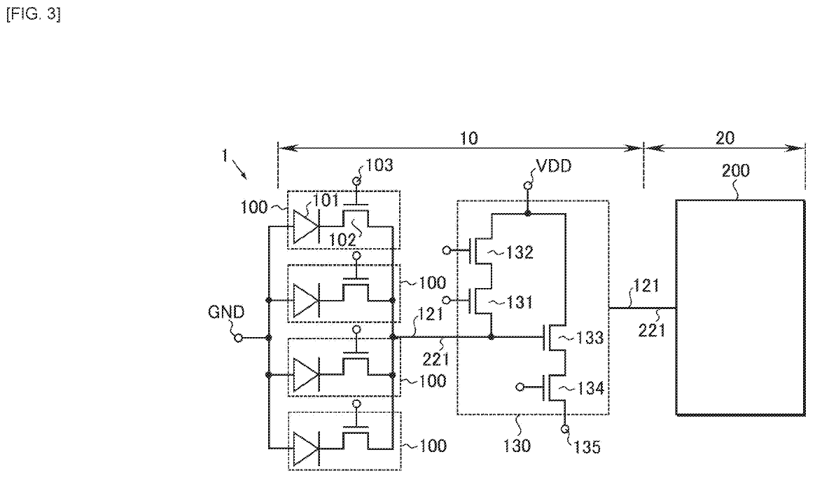

FIG. 3 illustrates an example of a circuit configuration of pixels 100, a pixel circuit 130, and an image processing circuit 200 that are included in the solid-state imaging device 1.

One pixel 100 includes a series circuit including a photoelectric conversion element (photodiode) 101 and a transfer transistor 102.

The photoelectric conversion element 101 converts light entered from outside of the solid-state imaging device 1 into an electric signal.

Another terminal of the transfer transistor 102 is coupled to the pixel circuit 130. The transfer transistor 102 and the pixel circuit 130 are coupled with a signal wiring line 121 interposed therebetween. Here, the signal wiring line 121 is a first signal wiring line or a second signal wiring line according to the present technology. A control terminal of the transfer transistor 102 is coupled to a horizontal signal line 103.

The pixel circuit 130 includes a floating diffusion (FD) conversion gain switching transistor 131, a reset transistor 132, an amplifier transistor 133, and a selection transistor 134.

Another terminal of the transfer transistor 102 is coupled to one terminal of the FD conversion gain switching transistor 131 and a control terminal of the amplifier transistor 133. Another terminal of the FD conversion gain switching transistor 131 is coupled to one terminal of the reset transistor 132. Another terminal of the reset transistor 132 is coupled to a power supply potential VDD. One terminal of the amplifier transistor 133 is coupled to one terminal of the selection transistor 134. Another terminal of the amplifier transistor 133 is coupled to the power supply potential VDD. Another terminal of the selection transistor 134 is coupled to a vertical signal line 135.

Moreover, the pixel circuit 130 is coupled to the image processing circuit 200. Although a detailed circuit configuration is omitted, the image processing circuit 200 includes an analog/digital converter (ADC) and a digital signal processor (DSP). The analog/digital converter converts an analog signal as an electric signal generated from light by the pixel 100 into a digital signal. The digital signal processor executes functional processing on the digital signal. That is, the image processing circuit 200 executes signal processing for creating an image.

The pixel circuit 130 and the image processing circuit 200 are coupled to each other with the signal wiring line 121 and a signal wiring line 221 interposed therebetween. Here, the signal wiring line 221 is a third signal wiring line and a fourth signal wiring line according to the present technology.

In the solid-state imaging device 1 according to the first embodiment, for example, one pixel circuit 130 is provided for four pixels 100. Of course, one pixel circuit 130 may be provided for one pixel 100.

### (2) Vertical Cross-Sectional Configuration of Solid-State Imaging Device 1

FIG. 1 illustrates an example of a vertical cross-sectional configuration of a portion of the pixels 100, the pixel circuit 130, and the image processing circuit 200 of the solid-state imaging device 1.

The solid-state imaging device 1 is configured as a back-illuminated image sensor here. As viewed in the arrow Y direction (hereinafter, simply referred to as “in a side view”), the solid-state imaging device 1 includes a first base 10 and a second base 20 that are sequentially stacked. The first base 10 is stacked on the second base 20, and the first base 20 is bonded to the second base 20.

The first base 10 includes a first semiconductor layer 11, and a first wiring layer 12 provided on a second base 20 side of the first semiconductor layer 11. The first semiconductor layer 11 includes silicon single crystal (Si).

The first semiconductor layer 11 includes the pixels 100 and the pixel circuit 130. Although a detailed structure of the photoelectric conversion element 101 of the pixel 100 is omitted, the photoelectric conversion element 101 includes an n-type semiconductor region and a p-type semiconductor region, and both the n-type semiconductor region and the p-type semiconductor region are pn-bonded.

On a side from which light enters of the photoelectric conversion element 101, a light receiving lens 13 is provided with a charge fixing film and an insulation film (not illustrated) interposed therebetween. Here, one light receiving lens 13 is provided for a total of four pixels 100 adjacent to each other in the arrow X direction and the arrow Y direction. Note that one light receiving lens 13 may be provided for one pixel 100. It is possible for the light receiving lens 13 to collect light entering the photoelectric conversion element 101.

Here, the side from which light enters is an opposite side to the second base 20 side of the first semiconductor layer 11.

Although a detailed structure of the transfer transistor 102 of the pixel 100 is similarly omitted, the transfer transistor 102 is formed on a surface portion on the second base 20 side of the first semiconductor layer 11. The transfer transistor 102 includes an n-channel insulated gate field effect transistor (IGFET). The transfer transistor 102 includes a pair of main electrodes (terminals) serving as a source region and a drain region, a channel forming region, a gate insulation film, and a gate electrode (control terminal).

Here, the IGFET includes at least a metallic body/oxide film/semiconductor type field effect transistor (MOSFET) and a metallic body/insulation body/semiconductor type field effect transistor (MISFET).

Furthermore, a pixel separation region 14 is provided between the pixels 100 adjacent to each other in the arrow X direction and the arrow Y direction. The pixel separation region 14 optically and electrically separates the adjacent pixels 100.

Furthermore, although a detailed structure is omitted, on the surface portion on the second substrate 20 side of the first semiconductor layer 11, the FD conversion gain switching transistor 131, the reset transistor 132, the amplifier transistor 133, and the selection transistor 134 included in the pixel circuit 130 are provided.

The first wiring layer 12 includes the signal wiring line 121, a signal terminal 123, a shield wiring line 122, a shield terminal 124, and an insulation body 125.

One end of the signal wiring line 121 is coupled to the transfer transistor 102, and another end of the signal wiring line 121 is coupled to the signal terminal 123. The signal wiring line 121 is configured as a through wiring line that passes through the first base 10 including the first semiconductor layer 11 and the first wiring layer 12 in the arrow Z direction that is a thickness direction. Although detailed description of the configuration and references are omitted, the signal wiring line 121 includes a plurality of layers of wiring lines and a plug wiring line for coupling the wiring lines. As wiring line materials of the wiring line and the plug wiring line, for example, copper (Cu) is used. Furthermore, as the wiring line material of the wiring line, for example, an aluminum (Al) alloy may be used, and as the wiring line material of the plug wiring line, for example, tungsten (W) may be used.

One end of the signal terminal 123 is coupled to the signal wiring line 121, and another end of the signal terminal 123 is exposed on the surface on the second base 20 side of the first wiring layer 12, that is, the surface of the insulation body 125. The exposed surface of the signal terminal 123 is used as a bonding surface to the second base 20. As a wiring line material of the signal terminal 123, for example, a metal such as copper is used.

Although a detailed arrangement layout is described later, the signal wiring line 121 and the signal terminal 123 are provided in a region corresponding to a center portion of the pixel 100.

The insulation body 125 includes each of the signal wiring line 121 and the signal terminal 123 embedded therein. The insulation body 125 is actually formed by stacking a plurality of insulation films. As the insulation body 125, for example, an insulation film (low-k film) having a low permittivity is used. Furthermore, the insulation body 125 may include a silicon oxide film (SiO), a silicon nitride film (SiN), or a combination of both.

One end of the shield wiring line 122 is coupled to the p-type semiconductor region of the photoelectric conversion element 101, and another end of the shield wiring line 122 is coupled to the shield terminal 124. The shield wiring line 122 is configured as a through wiring line that passes through the first base 10 in the thickness direction, similarly to the signal wiring line 121. Furthermore, the shield wiring line 122 includes a plurality of layers of wiring lines and a plug wiring line for coupling the wiring lines. A wiring line material of the wiring line and the plug wiring line of the shield wiring line 122 is the same as the wiring line material of the wiring line and the plug wiring line of the signal wiring line 121.

One end of the shield terminal 124 is coupled to the shield wiring line 122, and another end of the shield terminal 124 is exposed on the surface of the first wiring layer 12, similarly to the signal terminal 123. A wiring line material of the shield terminal 124 is the same as the wiring line material of the signal terminal 123.

Although a detailed arrangement layout is described later, the shield wiring line 122 is provided in a region corresponding to a peripheral portion of the pixel 100 and is provided along the circumference of the signal wiring line 121. Similarly, the shield terminal 124 is provided in a region corresponding to the peripheral portion of the pixel 100 and is provided along the circumference of the signal terminal 123. A power supply potential GND is applied to the shield wiring line 122 and the shield terminal 124.

Furthermore, the shield wiring line 122, and the shield terminal 124 excluding the exposed surface are embedded in the insulation body 125.

The second base 20 includes a second semiconductor layer 21, and a second wiring layer 22 provided on a first base 10 side of the second semiconductor layer 21. The second semiconductor layer 21 includes silicon single crystal, similarly to the first semiconductor layer 11.

The second semiconductor layer 21 includes the image processing circuit 200. The image processing circuit 200 includes a plurality of transistors 201. The transistor 201 is provided in a main surface portion on the first base 10 side of the second semiconductor layer 21. Here, the main surface portion is used to have the meaning of a major surface portion where an element such as a transistor or a resistor is formed.

The transistor 201 is provided in the main surface portion of the second semiconductor layer 21, in a region surrounded by an element separation region (not illustrated). The transistor 201 includes a pair of main electrodes 23, a channel forming region, a gate insulation film 24, and a gate electrode 25. The pair of main electrodes 23 includes a source region and a drain region, and includes an n-type semiconductor region. The channel forming region is formed by the second semiconductor layer 21 between the pair of main electrodes 23. The gate insulation film 24 is provided along the channel forming region and includes, for example, a silicon oxide film, a silicon nitride film, or a stacked film thereof. The gate electrode 25 is provided along the gate insulation film 24 and includes, for example, polycrystalline silicon. The transistor 201 includes the n-channel IGFET, similarly to the transfer transistor 102.

Note that the image processing circuit 200 may include a complementary IGFET including an n-channel IGFET and a p-channel IGFET.

The second wiring layer 22 includes the signal wiring line 221, a shield wiring line 222, a signal terminal 223, a shield terminal 224, and an insulation body 224.

One end of the signal wiring line 221 is coupled to the transistor 201, and another end of the signal wiring line 221 is coupled to the signal terminal 223. The signal wiring line 221 is configured as a through wiring line that passes through the second base 20 including the second semiconductor layer 21 and the second wiring layer 22 in the thickness direction. Although detailed description of the configuration and references are omitted, the signal wiring line 221 includes a plurality of layers of wiring lines and a plug wiring line for coupling the wiring lines, similarly to the signal wiring line 121. A wiring line material of the wiring line is the same as the wiring line material of the wiring line of the signal wiring line 121. Furthermore, a wiring line material of the plug wiring line is the same as the wiring line material of the plug wiring line of the signal wiring line 121.

One end of the signal terminal 223 is coupled to the signal wiring line 221, and another end of the signal terminal 223 is exposed on the surface on the first base 10 side of the second wiring layer 22, that is, the surface of the insulation body 225. The exposed surface of the signal terminal 223 is used as a bonding surface to the first base 10 and is bonded to the signal terminal 123 of the first base 10. A wiring line material of the signal terminal 223 is the same as the wiring line material of each of the signal terminal 123 and the shield terminal 124.

Although a detailed arrangement layout is described later similarly to the signal wiring line 121 and the signal terminal 123, the signal wiring line 221 and the signal terminal 223 are provided in a region corresponding to the center portion of the pixel 100.

The insulation body 225 includes each of the signal wiring line 221 and the signal terminal 223 embedded therein. The insulation body 225 includes a material similar to that of the insulation body 125.

One end of the shield wiring line 222 is coupled to the second semiconductor layer 21. Specifically, the shield wiring line 222 is coupled to a p-type semiconductor region (p-type well region) 26. Another end of the shield wiring line 222 is coupled to the shield terminal 224. The shield wiring line 222 is configured as a through wiring line that passes through the second base 20 in the thickness direction, similarly to the signal wiring line 221. Furthermore, the shield wiring line 222 includes a plurality of layers of wiring lines and a plug wiring line for coupling the wiring lines. A wiring line material of the wiring line and the plug wiring line of the shield wiring line 222 is the same as the wiring line material of the wiring line and the plug wiring line of the signal wiring line 221.

One end of the shield terminal 224 is coupled to the shield wiring line 222, and another end of the shield terminal 224 is exposed on the surface of the second wiring layer 22, similarly to the signal terminal 223. The exposed surface of the shield terminal 224 is used as a bonding surface to the first base 10 and is bonded to the shield terminal 124 of the first base 10. A wiring line material of the shield terminal 224 is the same as the wiring line material of the signal terminal 223.

Although a detailed arrangement layout is described later, the shield wiring line 222 is provided in a region corresponding to the peripheral portion of the pixel 100 and is provided along the circumference of the signal wiring line 221. Similarly, the shield terminal 224 is provided in a region corresponding to the peripheral portion of the pixel 100 and is provided along the circumference of the signal terminal 223.

Furthermore, the shield wiring line 222, and the shield terminal 224 excluding the exposed surface are embedded in the insulation body 225.

Here, in the solid-state imaging device 1 according to the first embodiment, a two-layer stacked structure including the first base 10 and the second base 20 is adopted. However, it is possible to adopt a three-layer stacked structure further including a third base. In this case, in the third base, for example, a memory such as a dynamic random access memory (DRAM) or a non-volatile memory, and a logic circuit for implementing an artificial intelligence (AI) function are provided.

### (3) Arrangement Layout of Signal Terminals 123 and Shield Terminals 124 of First Base 10

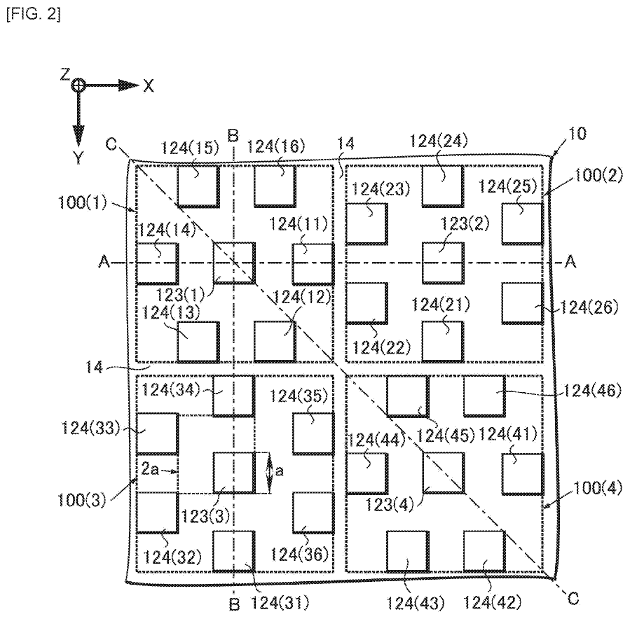

FIG. 2 illustrates an arrangement layout of the signal terminals 123 and the shield terminals 124 in the first wiring layer 12 of the first base 10 as viewed in the arrow Z direction (hereinafter, simply referred to as “in a plan view”).

For easy description, a region corresponding to the two pixels 100 adjacent to each other in the arrow X direction and the two pixels 100 adjacent to each other in the arrow Y direction, that is, the four pixels 100 in total, is indicated using a broken line. Here, the pixel 100 disposed at the upper left in FIG. 2 to be a starting point of an arrow is indicated by adding a reference (1), for convenience, and the pixel 100 disposed at the upper right is indicated by adding a reference (2). In addition, the pixel 100 disposed at the lower left is indicated by adding a reference (3), and the pixel 100 disposed at the lower right is indicated by adding a reference (4).

Each of the four pixels 100(1) to 100(4) is formed in a rectangular shape, more particularly, in a square shape, in a plan view. The pixel separation region 14 is provided between the pixels 100(1) and 100(2) adjacent to each other in the arrow X direction. Similarly, the pixel separation region 14 is provided between the pixels 100(3) and 100(4) adjacent to each other in the arrow X direction. Furthermore, the pixel separation region 14 is provided between the pixels 100(1) and 100(3) and between the pixels 100(2) and 100(4) adjacent to each other in the arrow Y direction.

In a region corresponding to a center portion of the pixel 100(1), one signal terminal 123 is provided on a surface portion on the second base 20 side of the first wiring layer 12. This signal terminal 123 corresponds to a first signal terminal according to the present technology. For convenience, the signal wiring line 123 is indicated by adding a reference (1). The signal terminal 123(1) is formed in a rectangular shape in a plan view, and more particularly, in a square shape that is a similar shape of the pixel 100(1).

In a case where allowable bonding accuracy for bonding between the signal terminal 123(1) and the signal terminal 223 (refer to FIG. 1) provided on the second base 20 is, for example, 0.5 μm, a dimension of one side of the rectangular shape of the signal terminal 123(1) is set to be less than or equal to 1.0 μm, for example. Furthermore, in a case where the bonding accuracy is, for example, 1.0 μm, the dimension of the one side of the signal terminal 123(1) is set to be less than or equal to 2.0 μm, for example. In addition, in a case where the signal terminal 123(1) includes, for example, copper, the dimension of the one side of the signal terminal 123(1) is set to be “a”, and a check area is set to be “2a”, a copper coverage is set to be higher than or equal to 15% and lower than or equal to 35%.

In a region corresponding to a peripheral portion of the pixel 100(1), six shield terminals 124 are provided on the surface portion on the second base 20 side of the first wiring layer 12. For convenience, the six shield terminals 124 are respectively indicated by adding references (11) to (16).

Each of the shield terminals 124(11) to 124(16) is formed in the rectangular shape that is the same as the shape of the signal terminal 123(1), in a plan view. Moreover, here, each of the shield terminals 124(11) to 124(16) is formed to have the same plane area as the signal terminal 123(1). In addition, each of the signal terminal 123(1) and the shield terminals 124(11) to 124(16) is formed by the same manufacturing process flow, in a manufacturing process of the solid-state imaging device 1. Therefore, each of the shield terminals 124(11) to 124(16) is formed to have the same volume as the signal terminal 123(1).

The shield terminal 124(11) is provided in a region corresponding to the pixel 100(2) side of the peripheral portion of the pixel 100(1). The shield terminal 124(11) corresponds to a first shield terminal according to the present technology. The side of the shield terminal 124(11) on the pixel 100(2) side matches the side of the pixel 100(1) on the pixel 100(2) side, in a plan view. In different expression, the side of the shield terminal 124(11) on the pixel 100(2) side matches an outline of the pixel separation region 14 on the pixel 100(1) side. Furthermore, in different expression, the shield terminal 124(11) is provided along a region corresponding to the side of the pixel 100(1) adjacent to the pixel 100(2).

Moreover, the center position of the shield terminal 124(11) matches a virtual line A-A, indicated for convenience, coupling the center of the signal terminal 123(1) to the center of the signal terminal 123(2) provided in a region corresponding to a center portion of the pixel 100(2). Furthermore, one shield terminal 124(11) is provided in a region corresponding to the side of the pixel 100(1) on the pixel 100(2) side.

In a region of the peripheral portion of the pixel 100(1) corresponding to the opposite side to the pixel 100(2) side, similarly to the shield terminal 124(11), the shield terminal 124(14) is provided. The center position of the shield wiring line 124(14) matches the virtual line A-A.

The shield terminals 124(12) and 124(13) are provided in a region corresponding to the pixel 100(3) side of the peripheral portion of the pixel 100(1). Similarly to the shield terminal 124(11), the sides on the pixel 100(3) side of the shield terminals 124(12) and 124(13) match the side of the pixel 100(1) on the pixel 100(3) side, in a plan view.

The shield terminals 124(12) and 124(13) are separated in the arrow X direction, with an interval exactly corresponding to one shield terminal 124. A virtual line B-B coupling the center of the signal terminal 123(1) to the center of the signal terminal 123(3) provided in a region corresponding to the center portion of the pixel 100(3) is illustrated for convenience. The shield terminal 124(12) is provided in a region displaced in the arrow X direction, with respect to the virtual line B-B. The shield terminal 124(13) is provided in a region displaced, with respect to the virtual line B-B, to the opposite side of the arrow X direction. A displacement amount of each of the shield terminals 124(12) and 124(13) is a half of the dimension of the side of the shield terminal 124, from the virtual line B-B. The shield terminals 124(12) and 124(13) correspond to a third shield terminal according to the present technology.

In a region corresponding to an opposite side of the pixel 100(3) side of the peripheral portion of the pixel 100(1), similarly to the shield terminals 124(12) and 124(13), the shield terminals 124(15) and 124(16) are provided. The shield terminal 124(15) is provided in a region displaced, with respect to the virtual line B-B, to the opposite side of the arrow X direction. The shield terminal 124(16) is provided in a region displaced in the arrow X direction, with respect to the virtual line B-B.

The shield terminals 124(11) to 124(16) are provided exactly in the clockwise direction around the signal terminal 123(1).

Similarly to the pixel 100(1), in a region corresponding to the pixel 100(2), one signal terminal 123 and six shield terminals 124 are provided. In the region corresponding to the pixel 100(2), the signal terminal 123 is indicated by adding a reference (2), for convenience. Furthermore, the shield terminals 124 are indicated by adding references (21) to (26).

As described above, the signal terminal 123(2) is provided in the region corresponding to the center portion of the pixel 100(2). The signal terminal 123(2) corresponds to a second signal terminal according to the present technology.

The shield terminals 124(21) to 124(26) are provided in a region corresponding to a peripheral portion of the pixel 100(2), similarly to the shield terminals 124(11) to 124(16).

In addition, the shield terminals 124(21) to 124(26) are provided at the positions where the positions of the shield terminals 124(11) to 124(16) are rotated by 90 degrees in the clockwise direction, around the signal terminal 123(2). In different expression, the signal terminal 123(1) and the shield terminals 124(11) to 124(16) provided in the region corresponding to the pixel 100(2) have the same configuration as and are rotated by 90 degrees from the signal terminal 123(1) and the shield terminals 124(11) to 124(16) provided in a region corresponding to the pixel 100(1).

Here, the shield terminals 124(22) and 124(23) are provided in the region corresponding to the pixel 100(1) side of the peripheral portion of the pixel 100(2). The shield terminals 124(22) and 124(23) corresponding to a second shield terminal according to the present technology. The sides of the shield terminals 124(22) and 124(23) on the pixel 100(1) side match the side of the pixel 100(2) on the pixel 100(1) side, in a plan view. In different expression, the shield terminals 124(22) and 124(23) are provided in the arrow X direction with the pixel separation region 14 interposed with respect to the shield terminal 124(11).

The shield terminal 124(22) is provided in a region displaced in the arrow Y direction, with respect to the virtual line A-A. The shield terminal 124(23) is provided in a region displaced, with respect to the virtual line A-A, to the opposite side of the arrow Y direction. That is, with respect to the shield terminal 124(11) provided in the region corresponding to the pixel 100(1), the shield terminals 124(22) and 124(23) provided in the region corresponding to the pixel 100(2) are provided in the region displaced in the arrow Y direction intersecting the arrow X direction.

Note that the shield terminal 124(21) corresponds to a fourth shield terminal according to the present technology.

Similarly to the pixel 100(2), in a region corresponding to the pixel 100(3), one signal terminal 123 and six shield terminals 124 are provided. In the region corresponding to the pixel 100(3), the signal terminal 123 is indicated by adding a reference (3), for convenience. Furthermore, the shield terminals 124 are indicated by adding references (31) to (36).

Here, a positional relationship between the shield terminal 124(34) provided in the region corresponding to the pixel 100(3) and the shield terminals 124(12) and 124(13) provided in the region corresponding to the pixel 100(1) is the same as a positional relationship between the shield terminal 124(11) provided in the region corresponding to the pixel 100(1) and the shield terminals 124(22) and 124(23) provided in the region corresponding to the pixel 100(2).

Similarly to the region corresponding to the pixel 100(1), in a region corresponding to the pixel 100(4), one signal terminal 123 and six shield terminals 124 are provided. In the region corresponding to the pixel 100(4), the signal terminal 123 is indicated by adding a reference (4), for convenience. Furthermore, the shield terminals 124 are indicated by adding references (41) to (46).

Here, a positional relationship between the shield terminal 124(44) provided in the region corresponding to the pixel 100(4) and the shield terminals 124(35) and 124(36) provided in the region corresponding to the pixel 100(3) is the same as the positional relationship between the shield terminal 124(11) provided in the region corresponding to the pixel 100(1) and the shield terminals 124(22) and 124(23) provided in the region corresponding to the pixel 100(2).

Furthermore, a positional relationship between the shield terminal 124(21) provided in the region corresponding to the pixel 100(2) and the shield terminals 124(45) and 124(46) provided in the region corresponding to the pixel 100(4) is the same as the positional relationship between the shield terminal 124(11) provided in the region corresponding to the pixel 100(1) and the shield terminals 124(22) and 124(23) provided in the region corresponding to the pixel 100(2).

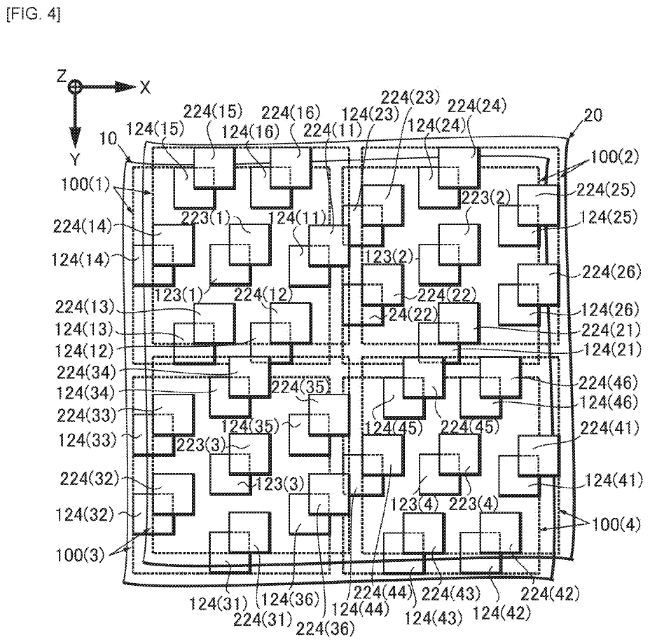

FIG. 4 illustrates an arrangement layout of the signal terminals 223 and the shield terminals 224 in the second wiring layer 22 of the second base 20, overlapping with the arrangement layout illustrated in FIG. 2. For easy understanding, both arrangement layouts are illustrated in a displaced state within the range of the bonding accuracy.

The signal terminals 223 and the shield terminals 224 provided in the second wiring layer 22 of the second base 20 are provided in the arrangement layout similar to that of the signal terminals 123 and the shield terminals 124 provided in the first wiring layer 12 of the first base 10. In the region corresponding to the pixel 100(1), one signal terminal 223 is provided in the center portion, and six shield terminals 224 are provided in the peripheral portion. As described above, the description is made as adding references, for convenience. That is, in the region corresponding to the pixel 100(1), the signal terminal 223(1) and the shield terminals 224(11) to 224(16) are provided. Here, the signal terminal 223(1) corresponds to a third signal terminal according to the present technology. Furthermore, the shield terminal 224(11) corresponds to a fifth shield terminal according to the present technology.

Similarly, in the region corresponding to the pixel 100(2), one signal terminal 223(2) is provided in the center portion, and six shield terminals 224(21) to 224(26) are provided in the peripheral portion. Here, the signal terminal 223(2) corresponds to a fourth signal terminal according to the present technology. Furthermore, the shield terminals 224(22) and 224(23) correspond to a sixth shield terminal according to the present technology.

In the region corresponding to the pixel 100(3), one signal terminal 223(3) is provided in the center portion, and six shield terminals 224(31) to 224(36) are provided in the peripheral portion. Then, in the region corresponding to the pixel 100(4), one signal terminal 223(4) is provided in the center portion, and six shield terminals 224(41) to 224(46) are provided in the peripheral portion.

### (4) Method of Manufacturing Signal Terminals 123 and 223 and Shield Terminals 124 and 224

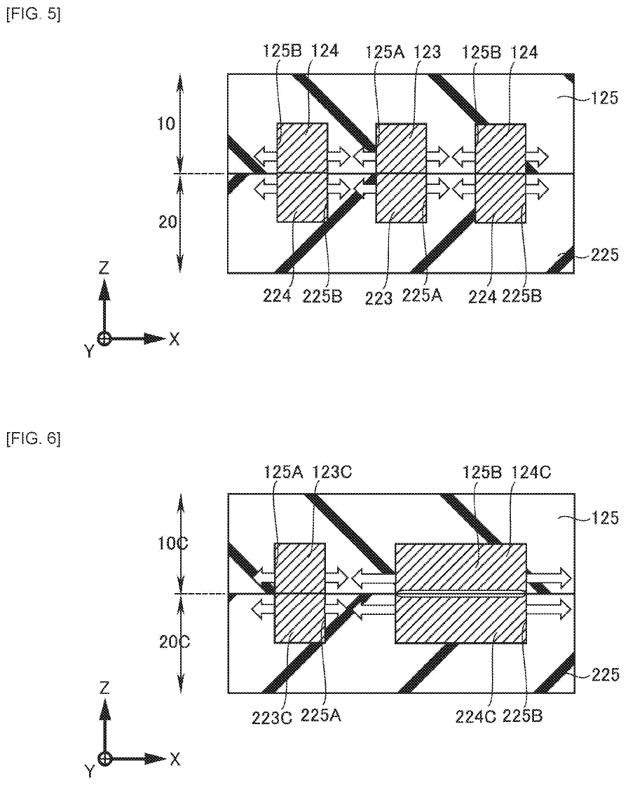

Next, a method of manufacturing the signal wiring line 123 and the shield terminal 124 of the solid-state imaging device 1 is briefly described with reference to FIG. 5. FIG. 5 illustrates a bonding state of the first base 10 and the second base 20.

Grooves 125A and 125B are formed in a surface portion of the insulation body 125 of the first base 10. The grooves 125A and 125B are formed by an etching technique, using a mask formed by a photolithography technique.

Next, for example, copper is formed on the surface of the insulation body 125. Copper is embedded in each of the grooves 125A and 125B. Then, redundant copper on the surface of the insulation body 125 is removed. As a result, the signal terminal 123 is formed in the groove 125A, and the shield terminal 124 is formed in the groove 125B. Chemical mechanical polishing (CMP) processing is used to remove the redundant copper.

By the similar manufacturing method, grooves 225A and 225B are formed in the insulation body 225 of the second base 20. Then, the signal terminal 223 is formed in the groove 225A, and the shield terminal 224 is formed in the groove 225B.

### Workings and Effects

As illustrated in FIG. 2, the solid-state imaging device 1 according to the first embodiment includes: the pixel 100(1) and the pixel 100(2); the signal terminal 123(1); the signal terminal 123(2); the shield terminal 124(11); and the shield terminal 124(22) and the shield terminal 124(23). The shield terminal 124(11) is provided in the region of the peripheral portion of the pixel 100(1) corresponding to the pixel 100(2) side, on the surface side of the first base 10. A fixed potential GND is supplied to the shield terminal 124(11). The shield terminals 124(22) and 124(23) are provided in the region corresponding to the pixel 100(1) side of the peripheral portion of the pixel 100(2), on the surface side of the first base 10, that is, the region displaced in the arrow Y direction with respect to the shield terminal 124(11). The fixed potential GND is supplied to the shield terminals 124(22) and 124(23). Here, in the first embodiment, the “fixed potential GND” is supplied to the shield terminal 124 etc., as a “fixed potential”. That is, the “fixed potential GND” is, for example, the ground. In the present technology, as long as a shield effect is obtained by the “fixed potential”, the “fixed potential” is not limited to the ground and may be a “fixed potential” fixed to a certain voltage. This applies similarly to the following embodiments.

That is, a shield region formed by the shield terminals 124(11), 124(22), and 124(22) is disposed between the signal terminal 123(1) of the pixel 100(1) and the signal terminal 123(2) of the pixel 100(2). Therefore, it is possible to effectively suppress or prevent noise propagation from one of the signal terminal 123(1) or the signal terminal 123(2) to the other, and this makes it possible to improve noise resistance performance of the solid-state imaging device 1. Similarly, it is possible to improve the noise resistance performance between the pixels 100(1) and 100(3) and between the pixels 100(2) and 100(4).

Note that, the shield terminal 124 is not particularly provided on a virtual line C-C (refer to FIG. 2) coupling the center position of the signal terminal 123(1) in the region corresponding to the pixel 100(1) to the center position of the signal terminal 123(4) corresponding to the pixel 100(4) provided in the oblique direction. In addition, the shield terminal 124 is not particularly provided on a virtual line (not illustrated) for coupling the center position of the signal terminal 123(2) in the region corresponding to the pixel 100(2) to the center position of the signal terminal 123(3) corresponding to the pixel 100(3) provided in the oblique direction. One reason for this is that a separation distance is longer than each of a separation distance between the signal terminal 123(1) and the signal terminal 123(2) provided on the virtual line A-A and a separation distance between the signal terminals 123(1) and 123(3) provided on the virtual line B-B, and an effect of noise is smaller.

Furthermore, as illustrated in FIG. 1, the signal wiring line 121 and the shield wiring line 122 of the first base 10 adopt the arrangement layout similar to that of the signal terminals 123 and the shield terminals 124 illustrated in FIG. 2. Therefore, it is possible to improve noise resistance performance between the signal wiring lines 121 of the pixels 100 adjacent to each other.

In addition, as illustrated in FIG. 2, with respect to the shield terminal 124(11) provided in the region corresponding to the pixel 100(1), the shield terminals 124(22) and 124(23) provided in the region corresponding to the pixel 100(2) are provided in a region displaced in the arrow Y direction. That is, it is possible to enlarge the shield region in the arrow Y direction with the three shield terminals 124(11), 124(22), and 124(23) in total. Therefore, it is possible to reduce the plane areas of the shield terminals 124(11), 124(22), and 124(23), in a plan view. Moreover, if the plane area is reduced, as illustrated in FIG. 5, it is possible to reduce the volumes of the shield terminals 124(11), 124(22), and 124(23). As a result, as illustrated in FIGS. 2 and 5, it is possible to form the shield terminal 124 to have the same plane area and the same volume as those of the signal terminal 123.

FIG. 6 illustrates a solid-state imaging device according to a comparative example and illustrates a bonding state of a first base 10C and a second base 20C. The first base 10C includes a signal terminal 123C, and a shield terminal 124C having a larger plane area and a larger volume than the signal terminal 123C. Similarly, the second base 20C includes a signal terminal 223C, and a shield terminal 224C having a larger plane area and a larger volume than the signal terminal 223C.

In the solid-state imaging device according to the comparative example configured in this way, pattern dependency occurs in chemical mechanical polishing processing in a manufacturing process, and accordingly, a recess (Cu recess) is easily generated in surfaces of the shield terminals 124C and 224C having the large plane areas. Unlike the comparative example, in the solid-state imaging device 1 according to the first embodiment, as illustrated in FIG. 5, the signal terminals 123 and 223 and the shield terminals 124 and 224 are formed to have the same plane area. Therefore, it is possible to effectively suppress or prevent the occurrence of the Cu recess, and this makes it possible to reliably bond the signal terminals 123 and 223, and it is possible to reliably bond the shield terminals 124 and 224.

In addition, in the solid-state imaging device according to the comparative example, as illustrated in FIG. 6, the volumes of the shield terminals 124C and 224C are larger than the volumes of the signal terminals 123C and 223C. Because copper has a larger linear coefficient of expansion with respect to silicon single crystal, the shield terminal 124C having the larger volume causes a stress. A thick arrow illustrated in FIG. 6 indicates a magnitude of the stress. Therefore, the first base 10C is easily warped. Similarly, the second base 20C is easily warped due to the shield terminal 224C having a larger volume.

Whereas, in the solid-state imaging device 1 according to the first embodiment, the shield terminal 124 is formed to have the same volume as the signal terminal 123, accordingly, the stress is small, and in addition, distribution of the stresses is equalized. Therefore, it is possible to effectively suppress or prevent the warpage of the first base 10. Similarly, the shield terminal 224 is formed to have the same volume as the signal terminal 223, and this makes it possible to effectively suppress or prevent the warpage of the second base 20.

Furthermore, in the solid-state imaging device 1 according to the first embodiment, as illustrated in FIG. 2, n-number of shield terminals 124(11), where “n” represents a natural number of more than or equal to one, are provided in the arrow Y direction, in the region corresponding to the pixel 100(1). Here, “n” is “1”. Then, n+1-number of shield terminals 124(22) and 124(23) are provided at certain intervals in the arrow Y direction in the region corresponding to the pixel 100(2). Here, “n+1” is “2”.

Therefore, it is possible to form the shield region between the signal terminals 123(1) and 123(2) with less number of shield terminals 124(11), 124(22), and 124(23).

Moreover, in the solid-state imaging device 1, as illustrated in FIG. 2, the plane of each of the signal terminals 123(1) and 123(2) and the shield terminals 124(11), 124(22), and 124(23) is formed in a rectangular shape, in a plan view. Therefore, the plane shape of each of the signal terminal 123 and the shield terminal 124 is formed to have the same shape, and this makes it possible to easily make the terminal arrangement layout.

Furthermore, in the solid-state imaging device 1, as illustrated in FIG. 2, each of the shield terminals 124(11), 124(22), and 124(23) has the same plane area. In addition, in the solid-state imaging device 1, as illustrated in FIG. 2, each of the signal terminals 123(1) and 123(2) and the shield terminals 124(11), 124(22), and 124(23) has the same plane area.

Therefore, it is possible to eliminate the pattern dependency as illustrated in FIG. 5, and this makes it possible to effectively suppress or prevent the Cu recess. Therefore, it is possible to reliably bond the bonding portion between the first base 10 and the second base 20 with no gap, and this makes it possible to improve electric reliability.

Moreover, in the solid-state imaging device 1, as illustrated in FIG. 2, the shield terminal 124(11) shields the noise from one of the signal terminal 123(1) or the signal terminal 123(2) to another terminal. Therefore, it is possible to improve the noise resistance performance.

Furthermore, in the solid-state imaging device 1, as illustrated in FIG. 2, the shield terminals 124(12) and 124(13) are provided in the region corresponding to the arrow Y direction side of the peripheral portion of the pixel 100(1). The shield terminal 124(21) is provided in the region corresponding to the arrow Y direction side of the peripheral portion of the pixel 100(2). Then, the shield terminals 124(21), 124(22), and 124(23) provided in the region corresponding to the pixel 100(2) are provided in the region where the shield terminals 124(11), 124(12), and 124(13) provided in the region corresponding to the pixel 100(1) are rotated by 90 degrees around the signal terminal 123(1).

Therefore, the signal terminal 123(1) and the shield terminals 124(11) to 124(16) provided in the region corresponding to the pixel 100(1) are repeatedly used as a basic arrangement layout, and this makes it possible to easily make the terminal arrangement layout.

Moreover, in the solid-state imaging device 1, as illustrated in FIGS. 1 and 2, the signal wiring line 121 and the shield wiring line 122 are provided in the region corresponding to the pixel 100(1). The signal wiring line 121 and the shield wiring line 122 have the same arrangement layout as the signal terminal 123(1) and the shield terminals 124(11) to 124(16). Similarly, the signal wiring line 121 and the shield wiring line 122 are provided in the region corresponding to the pixel 100(2). The signal wiring line 121 and the shield wiring line 122 have the same arrangement layout as the signal terminal 123(2) and the shield terminals 124(21) to 124(26).

Therefore, it is possible to improve the noise resistance performance between the signal wiring line 121 provided in the region corresponding to the pixel 100(1) and the signal wiring line 121 provided in the region corresponding to the pixel 100(2).

Furthermore, as illustrated in FIGS. 1 and 4, the solid-state imaging device 1 includes the second base 20, and the signal terminals 223 and the shield terminals 224 are included in the second base 20. For example, in the region corresponding to the pixel 100(1), the signal terminal 123(1) of the first base 10 and the signal terminal 223(1) of the second base 20 are bonded to each other. In addition, the shield terminals 124(11) to 124(16) and the shield terminals 224(11) to 224(16) are respectively bonded to each other. In the region corresponding to the pixel 100(2), the signal terminal 123(2) of the first base 10 and the signal terminal 223(2) of the second base 20 are bonded. In addition, the shield terminals 124(21) to 124(26) and the shield terminals 224(21) to 224(26) are respectively bonded to each other.

Therefore, it is possible to improve the noise resistance performance in the second base 20, and it is possible reliably bond the signal terminals 123 and 223 to each other and bond the shield terminals 124 and 224 to each other.

Note that, even if displacement occurs in the bonding between the first base 10 and the second base 20 within the range of the bonding accuracy, and the shield terminals 124 and 224 in the region corresponding to the adjacent pixels 100 are short-circuited, the same fixed potential GND is supplied to both. Therefore, there is no operation problem.

Moreover, in the solid-state imaging device 1, as illustrated in FIGS. 1 and 4, the position and the plane shape of the signal terminal 223 provided in the second base 20 are respectively the same as the position and the plane shape of the signal terminal 123 provided in the first base 20. In addition, the position and the plane shape of the shield terminal 224 provided in the second base 20 are respectively the same as the position and the plane shape of the shield terminal 124 provided in the first base 20.

Therefore, as illustrated in FIG. 5, it is possible to eliminate the pattern dependency in the second base 20, and this makes it possible to effectively suppress or prevent the Cu recess, for example. Therefore, it is possible to reliably bond the bonding portion between the first base 10 and the second base 20, and this makes it possible to improve the electric reliability.

Furthermore, in the solid-state imaging device 1, as illustrated in FIG. 2, as viewing the signal terminal 123(2) from the signal terminal 123(1) in the arrow X direction, the shield terminal 124(11) is formed to be entirely overlapped with the signal terminal 123(2) in the arrow Y direction. Therefore, it is possible to effectively suppress or prevent the noise propagation from one of the signal terminal 123(1) or the signal terminal 123(2) to another terminal, and this makes it possible to improve the noise resistance performance of the solid-state imaging device 1.

Note that it is possible to similarly obtain the workings and the effects described above between the pixels 100(1) and 100(3) and between the pixels 100(2) and 100(4), in addition to between the pixels 100(1) and 100(2).

### 2. Second Embodiment

A solid-state imaging device 1 according to a second embodiment of the present disclosure is described. Note that, in the second embodiment and the following embodiments, a component same as or substantially the same as the component of the solid-state imaging device 1 according to the first embodiment is denoted with the same reference numeral, and overlapping description is omitted.

### [Configuration of Solid-State Imaging Device 1]

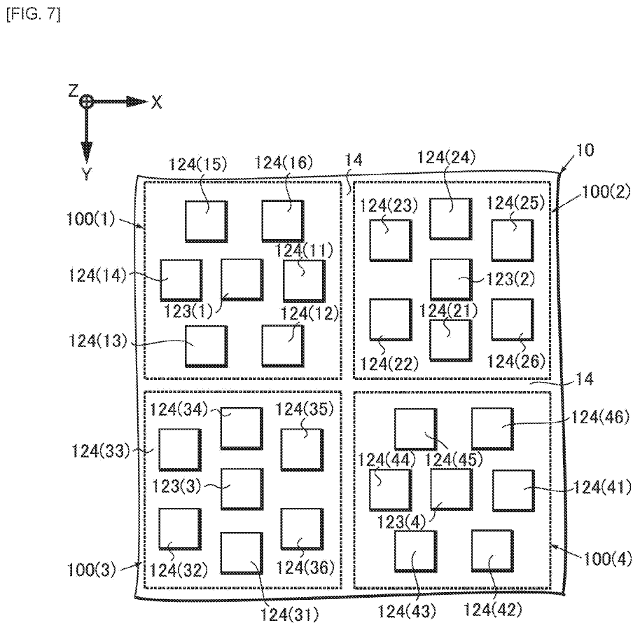

FIG. 7 illustrates an arrangement layout of the signal terminals 123 and the shield terminals 124 in the first base 10.

In the solid-state imaging device 1 according to the second embodiment, as illustrated in FIG. 7, in the region corresponding to the pixel 100, the shield terminal 124 is provided around the signal terminal 123 and to be closer to the signal terminal 123 side from the pixel separation region 14. That is, for example, a separation distance between the shield terminal 124(11) provided in the region corresponding to the pixel 100(1) and the shield terminals 124(22) and 124(23) provided in the region corresponding to the pixel 100(2) adjacent to the pixel 100(1) is secured.

Components other than the above are similar to the components of the solid-state imaging device 1 according to the first embodiment.

### Workings and Effects

According to the solid-state imaging device 1 according to the second embodiment, it is possible to obtain workings and effects similar to the workings and effects obtained by the solid-state imaging device 1 according to the first embodiment.

Furthermore, in the solid-state imaging device 1 according to the second embodiment, as illustrated in FIG. 7, it is possible to secure the separation distance between the shield terminals 124 in the region corresponding to the adjacent pixels 100, and this makes it easier to make a terminal arrangement layout.

Moreover, when displacement occurs in bonding between the first base 10 and the second base 20 within the range of the bonding accuracy, a short circuit between the shield terminals 124 and 224 in the region corresponding to the adjacent pixels 100 is prevented. Note that, as described above, there is no operation problem because the same fixed potential GND is supplied to each of the shield terminals 124 and 224.

### 3. Third Embodiment

A solid-state imaging device 1 according to a third embodiment of the present disclosure is described.

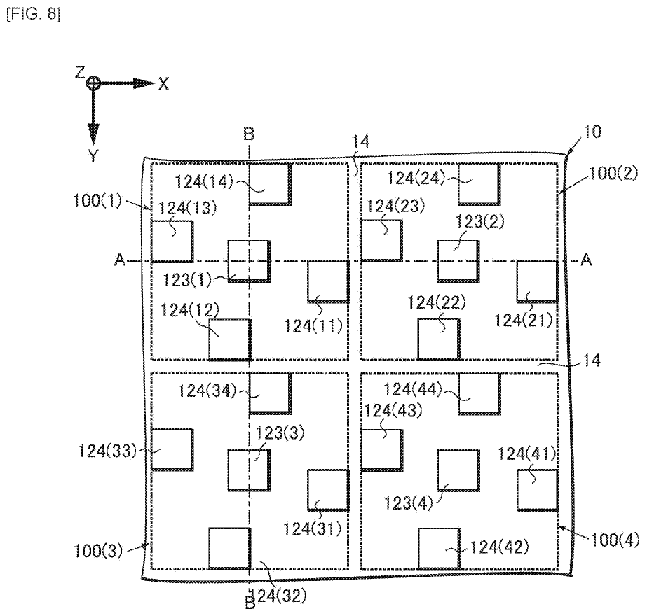

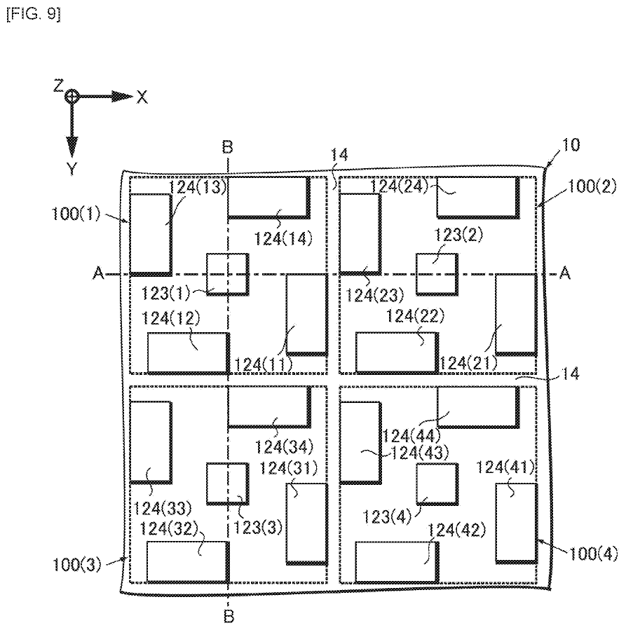

FIG. 8 illustrates an arrangement layout of the signal terminals 123 and the shield terminals 124 in the first base 10.

As illustrated in FIG. 8, the solid-state imaging device 1 according to the third embodiment includes one signal terminal 123 and four shield terminals 124 in the first base 10, in the region corresponding to the pixel 100.

More specifically, similarly to the solid-state imaging device 1 according to the first embodiment, the signal terminal 123(1) is provided in a region corresponding to a center portion of the pixel 100(1), and the four shield terminals 124(11) to 124(14) are provided in the region corresponding to the peripheral portion of the pixel 100(1). The shield terminals 124(11) to 124(14) are provided at respective sides of the region corresponding to the pixel 100(1).

In the region corresponding to the pixel 100(1), the shield terminal 124(11) on the side of the region corresponding to the pixel 100(2) is provided on the arrow Y direction side relative to the virtual line A-A. Here, the virtual line A-A matches a side opposite to the arrow Y direction of the shield terminal 124(11).

The shield terminal 124(12) on the side of the region corresponding to the pixel 100(3) is provided on the opposite side to the arrow X direction relative to the virtual line B-B. Here, the virtual line B-B matches the side on the opposite side to the arrow X direction of the shield terminal 124(12).

The shield terminal 124(13) provided on the opposite side to the shield terminal 124(11) centered on the signal terminal 123(1) is provided on the opposite side to the arrow Y direction relative to the virtual line A-A. Here, the virtual line A-A matches the side on the arrow Y direction side of the shield terminal 124(13).

The shield terminal 124(14) provided on the opposite side to the shield terminal 124(12) centered on the signal terminal 123(1) is provided on the arrow X direction side relative to the virtual line B-B. Here, the virtual line B-B matches the side on the opposite side to the arrow X direction of the shield terminal 124(14).

Assuming the signal terminal 123(1) and the shield terminals 124(11) to 124(14) in the region corresponding to the pixel 100(1) as a basic arrangement layout, the signal terminals 123 and the shield terminals 14 in regions corresponding to the pixels 100(2) to 100(4) are provided.

That is, the signal terminal 123(2) is provided in the region corresponding to the center portion of the pixel 100(2), and the shield terminals 124(21) to 124(24) are provided in the region corresponding to the peripheral portion of the pixel 100(2). The signal terminal 123(3) is provided in the region corresponding to the center portion of the pixel 100(3), and the shield terminals 124(31) to 124(34) are provided in the region corresponding to the peripheral portion of the pixel 100(3). Then, the signal terminal 123(4) is provided in the region corresponding to the center portion of the pixel 100(4), and the shield terminals 124(41) to 124(44) are provided in the region corresponding to the peripheral portion of the pixel 100(4).

In the solid-state imaging device 1 configured in this way, for example, the shield terminal 124(11) in the region corresponding to the pixel 100(1) is provided as being displaced to the arrow Y direction side relative to the virtual line A-A. Then, the shield terminal 124(23) in the region corresponding to the pixel 100(2) is provided as being displaced to the opposite side to the arrow Y direction relative to the virtual line A-A. That is, as viewing the signal terminal 123(2) from the signal terminal 123(1) side, the signal terminal 123(2) is shielded by the shield terminals 124(11) and 124(23).

Similarly, the shield terminal 124(12) in the region corresponding to the pixel 100(1) is provided as being displaced to the opposite side to the arrow X direction relative to the virtual line B-B. Then, the shield terminal 124(34) in the region corresponding to the pixel 100(3) is provided as being displaced to the arrow X direction side relative to the virtual line B-B. That is, as viewing the signal terminal 123(3) from the signal terminal 123(1) side, the signal terminal 123(3) is shielded by the shield terminals 124(12) and 124(34).

### Workings and Effects

According to the solid-state imaging device 1 according to the third embodiment, it is possible to obtain workings and effects similar to the workings and the effects obtained by the solid-state imaging device 1 according to the first embodiment.

Furthermore, in the solid-state imaging device 1 according to the third embodiment, as illustrated in FIG. 8, the shield terminal 124(11) in the region corresponding to the pixel 100(1) and the shield terminal 124(23) provided in the region corresponding to the pixel 100(2) are provided in the displaced regions with respect to the virtual line A-A. The shield terminals 124(11) and 124(23) are provided as shield regions. Similarly, the shield terminal 124(12) in the region corresponding to the pixel 100(1) and the shield terminal 124(24) in the region corresponding to the pixel 100(3) are provided as shield regions.

Therefore, it is possible to improve noise resistance performance. In addition, it is possible to reliably bond the signal terminal 123 to the signal terminal 223 of the second base 20 (refer to FIGS. 1 and 4) and bond the shield terminal 124 to the shield terminal 224 of the second base 20 (refer to FIGS. 1 and 4). Then, it is possible to effectively suppress or prevent warpage of each of the first base 10 and the second base 20.

### 4. Fourth Embodiment

A solid-state imaging device 1 according to a fourth embodiment of the present disclosure is described. In the fourth embodiment, an example in which the configuration of the shield terminal 124 of the solid-state imaging device 1 according to the third embodiment is changed is described.

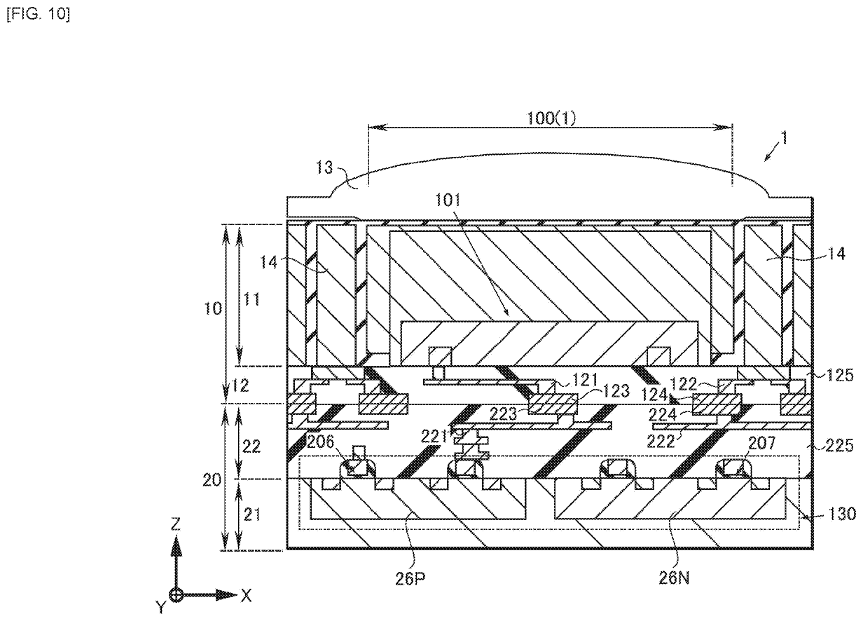

FIG. 9 illustrates an arrangement layout of the signal terminals 123 and the shield terminals 124 in the first base 10.

In the solid-state imaging device 1 according to the fourth embodiment, as illustrated in FIG. 9, a planar shape of the shield terminal 124 of the solid-state imaging device 1 according to the third embodiment is formed in a rectangular shape. Here, a plane area of the shield terminal 124 is doubled with respect to the plane area of the shield terminal 124 of the solid-state imaging device 1 according to the third embodiment. In different expression, a length of the shield terminal 124 is doubled, and the length of the shield terminal 124 is formed to be longer than a length of the signal terminal 123.

Components other than the above are the same as the components of the solid-state imaging device 1 according to the third embodiment.

### Workings and Effects

According to the solid-state imaging device 1 according to the fourth embodiment configured in this way, it is possible to obtain workings and effects similar to the workings and the effects obtained by the solid-state imaging device 1 according to the third embodiment.

Furthermore, the shield terminal 124 has a rectangular shape in the solid-state imaging device 1 according to the fourth embodiment, and this makes it possible to enlarge a shield region.

### 5. Fifth Embodiment

A solid-state imaging device 1 according to a fifth embodiment of the present disclosure is briefly described. In the fifth embodiment, an example is described in which the present technology is applied to the solid-state imaging device 1 that adopts a single photon avalanche diode (SPAD) structure.

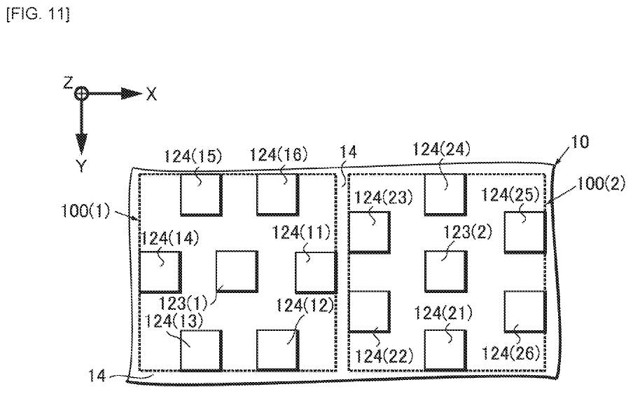

FIG. 10 illustrates an example of a vertical cross-sectional configuration of a portion of the pixel 100 and the pixel circuit 130 of the solid-state imaging device 1 that adopts a SPAD structure. Here, the SPAD structure is a pixel structure that uses “avalanche amplification” for amplifying electrons, like an avalanche, from entered photons.

In the solid-state imaging device 1, as illustrated in FIG. 10, the first base 10 and the second base 30 are bonded and stacked. A structure and description of a third base 30 where peripheral circuitry is mounted are omitted. The first base 10 includes the pixel 100 including the photoelectric conversion element 101.

Although description of the detailed structure is omitted, the photoelectric conversion element 101 includes a cathode region (n-type semiconductor region) and an anode region (p-type semiconductor region). The cathode region is coupled to the signal terminal 123 via the signal wiring line (cathode wiring line) 121. The anode region is coupled to the shield terminal 124 via the shield wiring line (anode wiring line) 122.

The second base 20 includes the pixel circuit (reading circuit) 130. The pixel circuit 130 includes a complementary IGFET mounted in the second semiconductor layer 21. The complementary IGFET includes an n-channel IGFET 206 formed in a p-type semiconductor region (p-type well region) 26P and a p-channel IGFET formed in an n-type semiconductor region (n-type well region) 26N.

The complementary IGFET is coupled to the signal terminal 223 via the signal wiring line 221. The p-type semiconductor region 26P is coupled to the shield terminal 224 via the shield wiring line 222. A fixed potential GND is supplied to the p-type semiconductor region 26P from the first base 10 or the third base 30 (not illustrated).

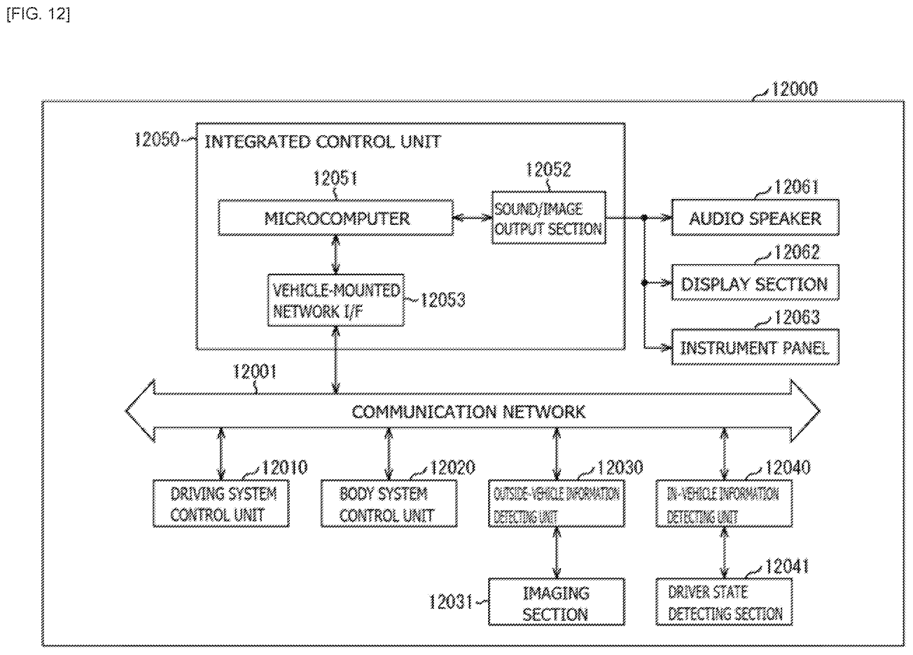

FIG. 11 illustrates an arrangement layout of the signal terminals 123 and the shield terminals 124 in the first base 10. Here, for easy description, an arrangement layout of a region corresponding to the two pixels 100(1) and 100(2) is illustrated.

Similarly, to the solid-state imaging device 1 according to the first embodiment, in the first base 10, the signal terminal 123(1) and the shield terminals 124(11) to 124(16) are provided in the region corresponding to the pixel 100(1). In the region corresponding to the pixel 100(2), the signal terminal 123(2) and the shield terminals 124(21) to 124(26) are provided.

Then, the shield terminal 124(11) in the region corresponding to the pixel 100(1) is provided in the region displaced with respect to the shield terminals 124(22) and 124(23) in the region corresponding to the pixel 100(2).

### Workings and Effects

According to the solid-state imaging device 1 according to the fifth embodiment configured in this way, it is possible to obtain workings and effects similar to the workings and the effects obtained by the solid-state imaging device 1 according to the first embodiment.

### 6. Example of Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

FIG. 12 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 12, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 12, an audio speaker 12061, a display section 12062, and an instrument panel 12063 are illustrated as the output device. The display section 12062 may, for example, include at least one of an on-board display and a head-up display.

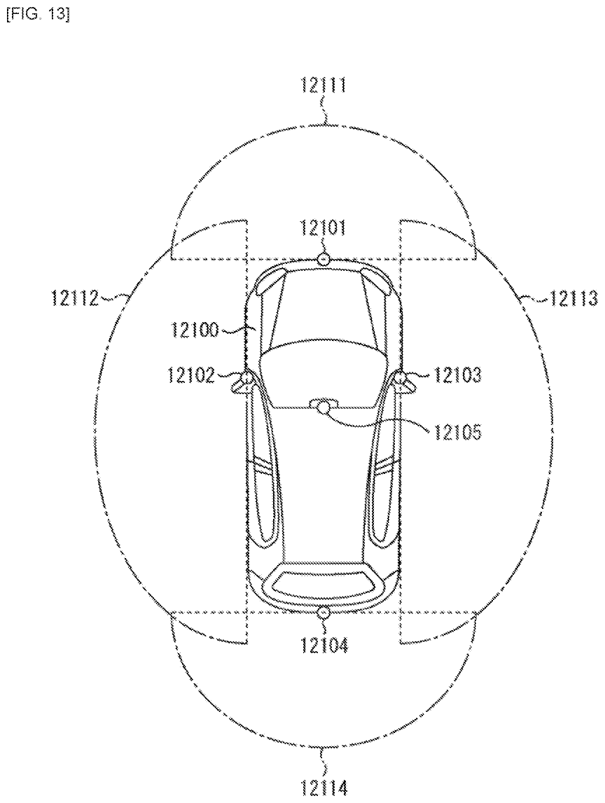

FIG. 13 is a diagram depicting an example of the installation position of the imaging section 12031.

In FIG. 13, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 13 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As described above, an example of the vehicle control system to which the technology of the present disclosure may be applied has been described. The technology of the present disclosure may be applied to the imaging section 12031, among the components described above. As a result of applying the technology of the present disclosure to the imaging section 12031, it is possible to implement the imaging section 12031 with a simpler configuration.

### 7. Example of Application to Endoscopic Surgery System

The technology of the present disclosure (present technology) is applicable to various products. For example, the technology of the present disclosure may be applied to an endoscopic surgery system.

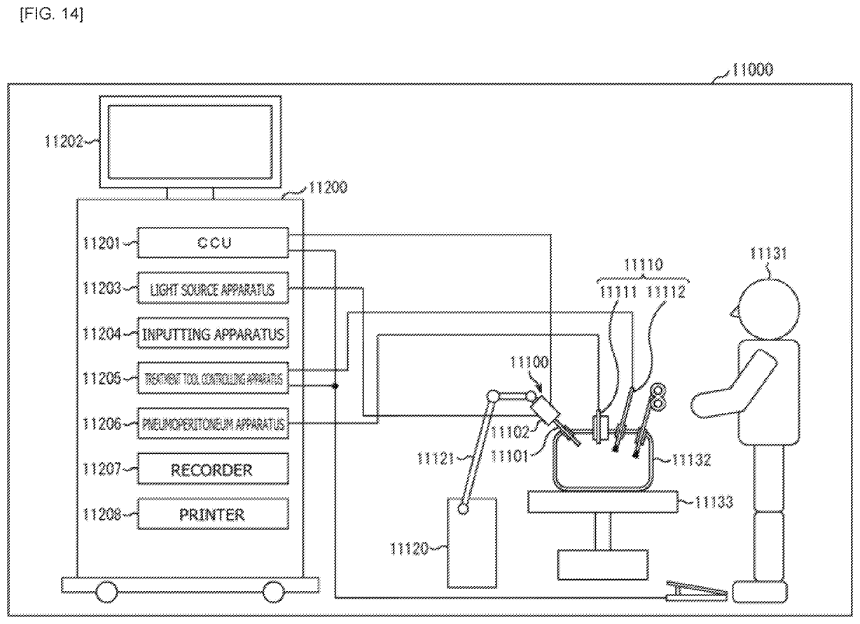

FIG. 14 is a view depicting an example of a schematic configuration of an endoscopic surgery system to which the technology according to an embodiment of the present disclosure (present technology) can be applied.

In FIG. 14, a state is illustrated in which a surgeon (medical doctor) 11131 is using an endoscopic surgery system 11000 to perform surgery for a patient 11132 on a patient bed 11133.

As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

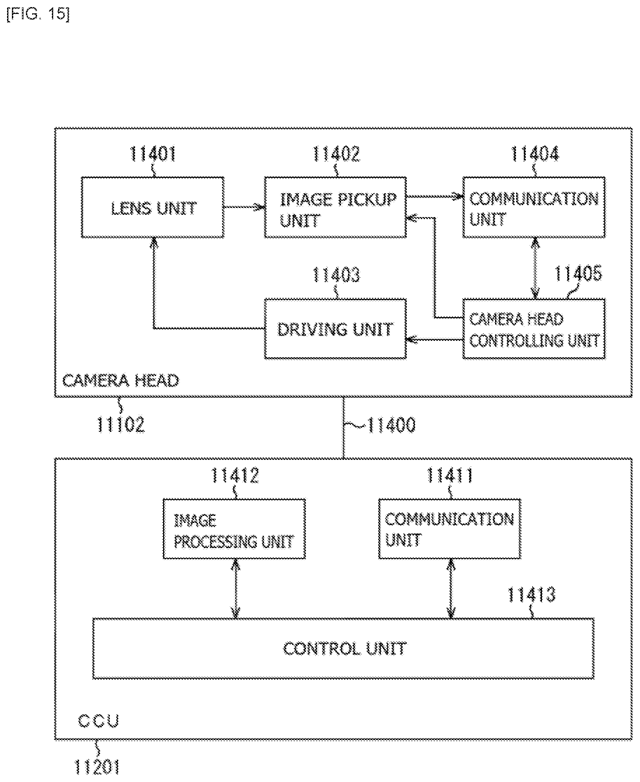

FIG. 15 is a block diagram depicting an example of a functional configuration of the camera head 11102 and the CCU 11201 depicted in FIG. 14.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As described above, an example of the endoscopic surgery system to which the technology of the present disclosure may be applied has been described. The technology of the present disclosure may be applied to, for example, the image pickup unit 11402 of the camera head 11102, among the components described above. As a result of applying the technology of the present disclosure to the image pickup unit 11402, it is possible to simplify the structure and obtain an excellent surgery site image.

Note that, here, the endoscopic surgery system has been described as an example. However, the technology of the present disclosure may be applied to other systems, for example, a microscope surgery system.

### 8. Example of Application to Electronic Apparatus

The solid-state imaging device 1 according to the embodiments described above is applicable to various types of an electronic apparatus 50, for example, an imaging device such as a digital still camera or a digital video camera, a mobile phone having an imaging function, or other devices having an imaging function.

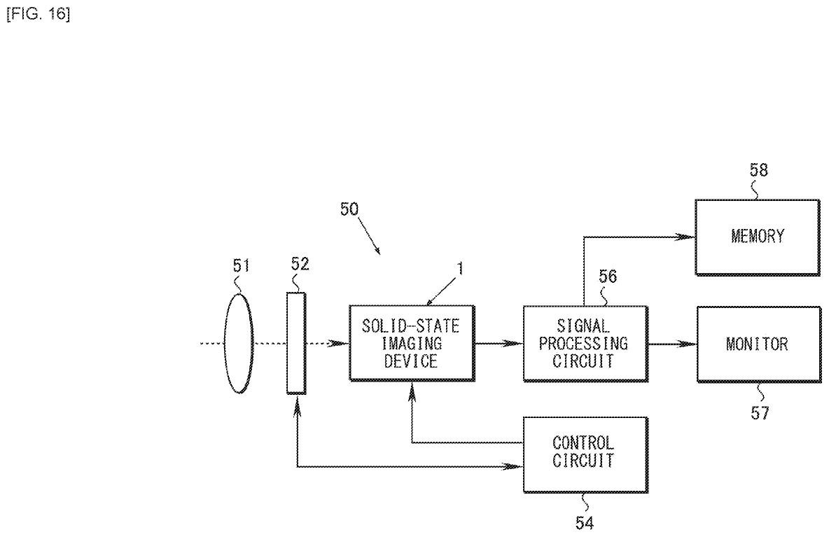

FIG. 16 illustrates a block diagram illustrating a configuration example of the electronic apparatus 50 to which the present technology is applied. The electronic apparatus 50 includes an optical system 51, a shutter device 52, the solid-state imaging device 1, a control circuit 54, a signal processing circuit 56, a monitor 57, and a memory 58. It is possible for the electronic apparatus 50 to capture a still image and a moving image.

The optical system 51 includes one or a plurality of lenses, guides light (incident light) from a subject to the solid-state imaging device 1, and forms an image on a light receiving surface of the solid-state imaging device 1.

The shutter device 52 is disposed between the optical system 51 and the solid-state imaging device 1. The shutter device 52 controls a light irradiation period and a light shielding period for the solid-state imaging device 1, under control of the control circuit 54.

The solid-state imaging device 1 is the solid-state imaging device 1 according to the embodiments described above and is packaged. The solid-state imaging device 1 accumulates signal charge, for a certain period, with the light of which the image is formed on the light receiving surface via the optical system 51 and the shutter device 52. The signal charge accumulated in the solid-state imaging device 1 is transferred to the signal processing circuit 56 in response to a driving signal (timing signal) supplied from the control circuit 54.

The control circuit 54 outputs the driving signal that controls a transfer operation of the solid-state imaging device 1 and a shutter operation of the shutter device 52. The solid-state imaging device 1 and the shutter device 52 are driven in response to the driving signal.

The signal processing circuit 56 executes various types of signal processing on the signal charge outputted from the solid-state imaging device 1. An image (image data) obtained by executing the signal processing by the signal processing circuit 56 is supplied to the monitor 57 and is displayed. Furthermore, the image is supplied to the memory 58 and is stored (recorded).

It is possible for the electronic apparatus 50 configured in this way to effectively suppress or prevent noise, similarly to the workings and the effects obtained by the solid-state imaging device 1 according to the embodiments.

### 9. Other Embodiments

The present technology is not limited to the above embodiments, and it is possible to variously modify the present technology without departing from the gist.

For example, the solid-state imaging devices according to the two or more embodiments, out of the solid-state imaging devices according to the first to fifth embodiments may be combined. In addition, although the present technology is applied to the solid-state imaging device including the two layers, that is, the first semiconductor layer and the second semiconductor layer, the present technology may be applied to a case where four or more semiconductor layers are included.

Furthermore, according to the present technology, in the region corresponding to the adjacent pixels, the shield terminal may be provided in the region corresponding to one pixel on the side of the region corresponding to another pixel, and it is not necessary to provide the shield terminal in the region corresponding to the other region on the side of the region corresponding to the one pixel.

Furthermore, according to the present technology, in the region corresponding to the adjacent pixels, the two or more shield terminals may be provided in the region corresponding to the one pixel on the side of the region corresponding to the other pixel, and three or more shield terminals may be provided in the region corresponding to the other pixel on the side of the region corresponding to the one pixel.

Moreover, according to the present technology, the plane of each of the signal terminal and the shield terminal may be formed in a triangular shape, a multangular shape having more than or equal to five corners, a circular shape, or an elliptical shape.

Furthermore, it is possible to widely apply the present technology to a light receiving device, a photoelectric conversion element, an optical detection device, etc., used for sensing applications, in addition to imaging applications. Moreover, the solid-state imaging device may use incident light of infrared light, ultraviolet light, or electromagnetic waves, for example, in addition to incident light of visible light. Furthermore, the present technology may have a configuration in which any desired color filter or band pass filter is provided above the side from which light enters of the photoelectric conversion element, and desired incident light is received.

According to the present disclosure, in the solid-state imaging device and the electronic apparatus, in the region corresponding to the adjacent pixels, the shield terminal in the region corresponding to the one pixel on the side of the region corresponding to the other pixel and the shield terminal in the region corresponding to the other pixel on the side of the region corresponding to the one pixel are provided in displaced regions. The fixed potential is supplied to the shield terminal.

As a result, the shield terminal is formed as the shield region, and this makes it possible to effectively suppress or prevent the noise between the adjacent pixels and to improve the electric reliability. In addition, the shield terminals are provided in the displaced regions, and this makes it possible to enlarge the shield region and reduce the plane area of the shield terminal. As a result, it is possible to reduce a difference between the respective plane areas of the signal terminal and the shield terminal, and it is possible to eliminate the pattern dependency in the manufacturing process. Therefore, it is possible to reliably bond the terminals between the stacked bases, and it is possible to improve the electric reliability.

### Configuration of Present Technology

The present technology has the following configuration. According to the present technology having the following configuration, it is possible to effectively suppress or prevent the noise between the adjacent pixels, to reliably bond the terminals between the stacked bases, and to improve the electric reliability.

(1)

A solid-state imaging device including:

a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel;

a first signal terminal that is provided in a region corresponding to a center portion of the first pixel, on a side of a second surface opposite to the side of the first surface of the first base, and is coupled to the first pixel;

a second signal terminal that is provided in a region corresponding to a center portion of the second pixel, on the side of the second surface of the first base, and is coupled to the second pixel;

a first shield terminal that is provided in a region corresponding to a side of the second pixel of a peripheral portion of the first pixel, on the side of the second surface of the first base, and is supplied with a fixed potential; and

a second shield terminal that is provided in a region corresponding to a side of the first pixel of a peripheral portion of the second pixel, on the side of the second surface of the first base, is provided in a region displaced in a second direction on the second surface intersecting the first direction with respect to the first shield terminal, and is supplied with a fixed potential.

(2)

The solid-state imaging device according to (1), in which a center position of the first shield terminal is provided on a second direction side with respect to a line coupling a center position of the first signal terminal to a center position of the second signal terminal, and a center position of the second shield terminal is provided on a side opposite to the second direction side.

(3)

The solid-state imaging device according to (1) or (2), in which

the first shield terminal comprises n-number of first shield terminals provided in the second direction, where “n” represents a natural number of more than or equal to one, and

the second shield terminal comprises n+1-number of second shield terminals provided in the second direction at certain intervals.

(4)

The solid-state imaging device according to any one of (1) to (3), in which as viewed from a thickness direction of the first base, a plane of each of the first signal terminal, the second signal terminal, the first shield terminal, and the second shield terminal has a rectangular shape.

(5)

The solid-state imaging device according to any one of (1) to (4), in which respective plane areas of the first shield terminal and the second shield terminal are equal to each other.

(6)

The solid-state imaging device according to any one of (1) to (4), in which respective plane areas of the first signal terminal, the second signal terminal, the first shield terminal, and the second shield terminal are equal to each other.

(7)

The solid-state imaging device according to (4), in which respective lengths of the first shield terminal and the second shield terminal in the second direction are longer than respective lengths of the first signal terminal and the second signal terminal in the second direction.

(8)

The solid-state imaging device according to any one of (1) to (7), in which noise from one of the first signal terminal or the second signal terminal to another one of the first signal terminal or the second signal terminal is shielded by at least one of the first shield terminal or the second shield terminal.

(9)

The solid-state imaging device according to (1), further including:

a third shield terminal that is provided in a region corresponding to the second direction side of the peripheral portion of the first pixel, on the side of the second surface of the first base; and

a fourth shield terminal that is provided in a region corresponding to the second direction side of the peripheral portion of the second pixel, on the side of the second surface of the first base, in which

the second shield terminal and the fourth shield terminal provided in the region corresponding to the second pixel are provided in a region where the first shield terminal and the third shield terminal provided in the region corresponding to the first pixel are rotated by 90 degrees around the first signal terminal.

(10)

The solid-state imaging device according to any one of (1) to (10), further including:

a first signal wiring line that extends in the first base in a thickness direction in the region corresponding to the first pixel and couples the first photoelectric conversion element and the first signal terminal to each other, and a first shield wiring line that extends in the first base in the thickness direction around the first signal wiring line and is coupled to the first shield terminal; and

a second signal wiring line that extends in the first base in the thickness direction in the region corresponding to the second pixel and couples the second photoelectric conversion element and the second signal terminal to each other, and a second shield wiring line that extends in the first base in the thickness direction around the second signal wiring line and is coupled to the second shield terminal.

(11)

The solid-state imaging device according to (1), further including:

a second base that has a third surface faced to the second surface and is stacked on the first base;

a third signal terminal that is provided on a side of the third surface of the second base, is bonded to the first signal terminal, and is coupled to a pixel circuit provided on a side of a fourth surface opposite to the side of the third surface of the second base;

a fourth signal terminal that is provided on the side of the third surface of the second base, is bonded to the second signal terminal, and is coupled to the pixel circuit;

a fifth shield terminal that is provided on the side of the third surface of the second base and is bonded to the first shield terminal; and

a sixth shield terminal that is provided on the side of the third surface of the second base and is bonded to the second shield terminal.

(12)

The solid-state imaging device according to (11), in which

as viewed from a thickness direction of the second base, a provided position and a plane shape of the third signal terminal are the same as a provided position and a plane shape of the first signal terminal,

a provided position and a plane shape of the fourth signal terminal are the same as a provided position and a plane shape of the second signal terminal,

a provided position and a plane shape of the fifth shield terminal are the same as a provided position and a plane shape of the first shield terminal, and

a provided position and a plane shape of the sixth shield terminal are the same as a provided position and a plane shape of the second shield terminal.

(13)

The solid-state imaging device according to (12), in which the first signal terminal, the second signal terminal, the third signal terminal, the fourth signal terminal, the first shield terminal, the second shield terminal, the fifth shield terminal, and the sixth shield terminal each include copper of which a surface is polished using chemical mechanical polishing processing.

(14)

A solid-state imaging device including:

a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel;

a first signal terminal that is provided in a region corresponding to a center portion of the first pixel, on a side of a second surface opposite to the side of the first surface of the first base, and is coupled to the first pixel;

a second signal terminal that is provided in a region corresponding to a center portion of the second pixel, on the side of the second surface of the first base, and is coupled to the second pixel; and

a first shield terminal that is provided in a region corresponding to a side of the second pixel of a peripheral portion of the first pixel, on the side of the second surface of the first base, is formed to be entirely overlapped with the second signal terminal in a second direction on the second surface intersecting the first direction, as viewing the second signal terminal from the first signal terminal in the first direction, and is supplied with a fixed potential.

(15)

An electronic apparatus including:

a solid-state imaging device, in which

the solid-state imaging device includes

a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel,

a first signal terminal that is provided in a region corresponding to a center portion of the first pixel, on a side of a second surface opposite to the side of the first surface of the first base, and is coupled to the first pixel,

a second signal terminal that is provided in a region corresponding to a center portion of the second pixel, on the side of the second surface of the first base, and is coupled to the second pixel,

a first shield terminal that is provided in a region corresponding to a side of the second pixel of a peripheral portion of the first pixel, on the side of the second surface of the first base, and is supplied with a fixed potential, and

a second shield terminal that is provided in a region corresponding to a side of the first pixel of a peripheral portion of the second pixel, on the side of the second surface of the first base, is provided in a region displaced in a second direction on the second surface intersecting the first direction with respect to the first shield terminal, and is supplied with a fixed potential.

(16)

An electronic apparatus including:

a solid-state imaging device, in which

the solid-state imaging device includes

a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel,

a first signal terminal that is provided in a region corresponding to a center portion of the first pixel, on a side of a second surface opposite to the side of the first surface of the first base, and is coupled to the first pixel,

a second signal terminal that is provided in a region corresponding to a center portion of the second pixel, on the side of the second surface of the first base, and is coupled to the second pixel, and

a first shield terminal that is provided in a region corresponding to a side of the second pixel of a peripheral portion of the first pixel, on the side of the second surface of the first base, is formed to be entirely overlapped with the second signal terminal in a second direction on the second surface intersecting the first direction, as viewing the second signal terminal from the first signal terminal in the first direction, and is supplied with a fixed potential.

This application claims the benefit of Japanese Priority Patent Application JP2021-83485 filed with the Japan Patent Office on May 17, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging device comprising:
a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel;
a first signal terminal that is provided in a region corresponding to a center portion of the first pixel, on a side of a second surface opposite to the side of the first surface of the first base, and is coupled to the first pixel;
a second signal terminal that is provided in a region corresponding to a center portion of the second pixel, on the side of the second surface of the first base, and is coupled to the second pixel;
a first shield terminal that is provided in a region corresponding to a side of the second pixel of a peripheral portion of the first pixel, on the side of the second surface of the first base, and is supplied with a fixed potential; and
a second shield terminal that is provided in a region corresponding to a side of the first pixel of a peripheral portion of the second pixel, on the side of the second surface of the first base, is provided in a region displaced in a second direction on the second surface intersecting the first direction with respect to the first shield terminal, and is supplied with a fixed potential.

2. The solid-state imaging device according to claim 1, wherein a center position of the first shield terminal is provided on a second direction side with respect to a line coupling a center position of the first signal terminal to a center position of the second signal terminal, and a center position of the second shield terminal is provided on a side opposite to the second direction side.

3. The solid-state imaging device according to claim 1, wherein
the first shield terminal comprises n-number of first shield terminals provided in the second direction, where “n” represents a natural number of more than or equal to one, and
the second shield terminal comprises n+1-number of second shield terminals provided in the second direction at certain intervals.

4. The solid-state imaging device according to claim 1, wherein, as viewed from a thickness direction of the first base, a plane of each of the first signal terminal, the second signal terminal, the first shield terminal, and the second shield terminal has a rectangular shape.

5. The solid-state imaging device according to claim 4, wherein respective plane areas of the first shield terminal and the second shield terminal are equal to each other.

6. The solid-state imaging device according to claim 4, wherein respective plane areas of the first signal terminal, the second signal terminal, the first shield terminal, and the second shield terminal are equal to each other.

7. The solid-state imaging device according to claim 4, wherein respective lengths of the first shield terminal and the second shield terminal in the second direction are longer than respective lengths of the first signal terminal and the second signal terminal in the second direction.

8. The solid-state imaging device according to claim 1, wherein noise from one of the first signal terminal or the second signal terminal to another one of the first signal terminal or the second signal terminal is shielded by at least one of the first shield terminal or the second shield terminal.

9. The solid-state imaging device according to claim 1, further comprising:
a third shield terminal that is provided in a region corresponding to the second direction side of the peripheral portion of the first pixel, on the side of the second surface of the first base; and
a fourth shield terminal that is provided in a region corresponding to the second direction side of the peripheral portion of the second pixel, on the side of the second surface of the first base, wherein
the second shield terminal and the fourth shield terminal provided in the region corresponding to the second pixel are provided in a region where the first shield terminal and the third shield terminal provided in the region corresponding to the first pixel are rotated by 90 degrees around the first signal terminal.

10. The solid-state imaging device according to claim 1, further comprising:
a first signal wiring line that extends in the first base in a thickness direction in the region corresponding to the first pixel and couples the first photoelectric conversion element and the first signal terminal to each other, and a first shield wiring line that extends in the first base in the thickness direction around the first signal wiring line and is coupled to the first shield terminal; and
a second signal wiring line that extends in the first base in the thickness direction in the region corresponding to the second pixel and couples the second photoelectric conversion element and the second signal terminal to each other, and a second shield wiring line that extends in the first base in the thickness direction around the second signal wiring line and is coupled to the second shield terminal.

11. The solid-state imaging device according to claim 1, further comprising:
a second base that has a third surface faced to the second surface and is stacked on the first base;
a third signal terminal that is provided on a side of the third surface of the second base, is bonded to the first signal terminal, and is coupled to a pixel circuit provided on a side of a fourth surface opposite to the side of the third surface of the second base;
a fourth signal terminal that is provided on the side of the third surface of the second base, is bonded to the second signal terminal, and is coupled to the pixel circuit;
a fifth shield terminal that is provided on the side of the third surface of the second base and is bonded to the first shield terminal; and
a sixth shield terminal that is provided on the side of the third surface of the second base and is bonded to the second shield terminal.

12. The solid-state imaging device according to claim 11, wherein
as viewed from a thickness direction of the second base, a provided position and a plane shape of the third signal terminal are the same as a provided position and a plane shape of the first signal terminal,
a provided position and a plane shape of the fourth signal terminal are the same as a provided position and a plane shape of the second signal terminal,
a provided position and a plane shape of the fifth shield terminal are the same as a provided position and a plane shape of the first shield terminal, and
a provided position and a plane shape of the sixth shield terminal are the same as a provided position and a plane shape of the second shield terminal.

13. The solid-state imaging device according to claim 12, wherein the first signal terminal, the second signal terminal, the third signal terminal, the fourth signal terminal, the first shield terminal, the second shield terminal, the fifth shield terminal, and the sixth shield terminal each include copper of which a surface is polished using chemical mechanical polishing processing.

14. A solid-state imaging device comprising:
a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel;
a first signal terminal that is provided in a region corresponding to a center portion of the first pixel, on a side of a second surface opposite to the side of the first surface of the first base, and is coupled to the first pixel;
a second signal terminal that is provided in a region corresponding to a center portion of the second pixel, on the side of the second surface of the first base, and is coupled to the second pixel; and
a first shield terminal that is provided in a region corresponding to a side of the second pixel of a peripheral portion of the first pixel, on the side of the second surface of the first base, is formed to be entirely overlapped with the second signal terminal in a second direction on the second surface intersecting the first direction, as viewing the second signal terminal from the first signal terminal in the first direction, and is supplied with a fixed potential.

15. An electronic apparatus comprising:
a solid-state imaging device, wherein
the solid-state imaging device includes
a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel,
a first signal terminal that is provided in a region corresponding to a center portion of the first pixel, on a side of a second surface opposite to the side of the first surface of the first base, and is coupled to the first pixel,
a second signal terminal that is provided in a region corresponding to a center portion of the second pixel, on the side of the second surface of the first base, and is coupled to the second pixel,
a first shield terminal that is provided in a region corresponding to a side of the second pixel of a peripheral portion of the first pixel, on the side of the second surface of the first base, and is supplied with a fixed potential, and
a second shield terminal that is provided in a region corresponding to a side of the first pixel of a peripheral portion of the second pixel, on the side of the second surface of the first base, is provided in a region displaced in a second direction on the second surface intersecting the first direction with respect to the first shield terminal, and is supplied with a fixed potential.

16. An electronic apparatus comprising:
a solid-state imaging device, wherein
the solid-state imaging device includes
a first pixel that is provided on a side of a first surface serving as a side from which light enters of a first base and includes a first photoelectric conversion element, and a second pixel that includes a second photoelectric conversion element and is disposed in a first direction on the first surface to be adjacent to the first pixel,
a first signal terminal that is provided in a region corresponding to a center portion of the first pixel, on a side of a second surface opposite to the side of the first surface of the first base, and is coupled to the first pixel,
a second signal terminal that is provided in a region corresponding to a center portion of the second pixel, on the side of the second surface of the first base, and is coupled to the second pixel, and
a first shield terminal that is provided in a region corresponding to a side of the second pixel of a peripheral portion of the first pixel, on the side of the second surface of the first base, is formed to be entirely overlapped with the second signal terminal in a second direction on the second surface intersecting the first direction, as viewing the second signal terminal from the first signal terminal in the first direction, and is supplied with a fixed potential.
